(19) United States
(12) Patent Application Publication
(10) Pub. No.: US 2007/0042600 A1
(43) Pub. Date: Feb. 22, 2007

(54) Method for fabricating semiconductor device

(76) Inventor: Shinji Takeoka, Osaka (JP)

Correspondence Address: MCDERMOTT WILL & EMERY LLP, 600 13TH STREET, N.W., WASHINGTON, DC, 20005-3096, US

(21) Appl. No.: 11/491,223

(22) Filed: Jul. 24, 2006

(30) Foreign Application Priority Data
Aug. 22, 2005 (JP) 2005-239527

(51) Int. Cl. H01L 21/4763

(52) U.S. Cl. 438/638; 438/648; 257/E21.579

(57) ABSTRACT

In a Cu interconnect process, an organic-based low-dielectric-constant interlayer film is formed, and then a protective film is deposited on the side and back surfaces of a wafer bevel and the back surface of a wafer edge. Thereafter, a lithography process and an etching process are carried out, a copper film is formed, and then the protective film is removed.

### BACKGROUND OF THE INVENTION

(a) Fields of the Invention

The present invention relates to methods for fabricating a semiconductor device, and in particular to interconnect formation processes using an insulating-layer formation material and a metal material serving as an interconnect layer.

(b) Description of Related Art

With shrinking design rules of semiconductor devices, circuit integration in the devices dramatically increases, so that more than one hundred million transistors can be provided on one chip. To provide such a chip, not only microfabrication technologies such as lithography and etching are developed which require a processing accuracy of the order of several tens of nanometers, but also lowered resistance of interconnects, lowered dielectric constant of interlayer insulating films, and multi-layer interconnection are needed.

A method for forming an interconnect of a semiconductor device using a low dielectric constant insulating material (referred hereinafter to as a low-k material) includes, for example, a Cu dual-damacene technique (see Japanese Unexamined Patent Publication No. 2003-23072). Hereinafter, a formation process of Cu dual-damacene interconnects will be described according to views of process steps in FIG. 4. FIGS. 4A to 4O are sectional views showing conventional interconnect formation steps.

A first description will be made of a formation method of an interlayer insulating film. Referring to FIGS. 4A and 4B, a barrier metal 102 and a copper interconnect layer 103 are formed which are buried in a first low-dielectric-constant interlayer film (referred hereinafter to as a first low-k interlayer film) 101. Subsequently, over a substrate, a liner film 104 of, for example, SiCN is formed by a plasma CVD method. Then, as shown in FIG. 4C, a second low-dielectric-constant interlayer film (referred hereinafter to as a second low-k interlayer film) 105 of, for example, SiOC is deposited on the liner film 104. As shown in FIG. 4D, using a chemical mechanical polishing method (referred hereinafter to as a CMP method), the second low-k interlayer film 105 is polished to have a predetermined thickness. Thereafter, as shown in FIG. 4E, a cap layer 106 of a silicon oxide film formed by a plasma CVD method is deposited on the second low-k interlayer film 105.

Next, the low-k interlayer film 105 and the cap layer 106 formed by the procedure shown above are subjected to patterning using a lithography technology and a dry etching technology. First, as shown in FIG. 4F, a photoresist film 107 is applied over the top surface of the substrate, and patterning by a lithography technology is conducted to form a hole-shaped opening through the photoresist film 107. Then, as shown in FIG. 4G, using the resulting photoresist film 107 as a mask, the cap layer 106 and the second low-k interlayer film 105 are dry etched to form a hole-shaped opening (a via hole). As shown in FIGS. 4H and 4I, the photoresist film 107 and a polymer or the like generated during the etching are removed, and then the via hole is filled with a photoresist to form a photoresist filling layer 108. Thereafter, as shown in FIG. 4J, a photoresist film 109 is applied to the substrate, and using a lithography technology, the photoresist film 109 is formed with a groove-shaped opening. As shown in FIG. 4K, using the resulting photoresist film 109 as a mask, the cap layer 106 and the second low-k interlayer film 105 are dry etched to form a groove-shaped opening, and then the photoresist film 109 and the photoresist filling layer 108 are removed. Subsequently, as shown in FIG. 4L, using an etch back method, a portion of the liner film 104 located on the copper interconnect layer 103 is removed to form an opened portion. During this removal, the cap layer 106 is also removed by the etch back.

Next, an interconnect layer is formed in the interlayer insulating film with the opening formed therein. First, as shown in FIG. 4M, by a sputtering method, a barrier metal 110 is deposited which is made of, for example, a stacked film of Ta and TaN. As shown in FIG. 4N, a Cu seed layer is formed by a sputtering method, and on this layer, copper is deposited by a plating method to form a copper film 111. Thereafter, a portion of the copper film 111 adhering to a wafer edge is wet etched. As shown in FIG. 4O, unnecessary portions of the barrier metal 110 and the copper film 111 are removed by a CMP method (Cu-CMP) to form an interconnect layer in the insulating film.

Through the process steps described above, an interconnect layer of a single layer is formed. By repeatedly conducting the steps shown in FIGS. 4A to 4O, multilayer interconnects can be fabricated.

### SUMMARY OF THE INVENTION

When the interconnect layer is formed by the above process steps, however, delamination from the edge of the wafer occurs to affect the yield of the device. The term “the edge of a wafer (or a wafer edge)” in this description means a region of a wafer located outside a chip formation region (semiconductor element formation region), while the term “a bevel (or a wafer bevel)” means a portion of a wafer contained in the wafer edge and having the surface inclined relative to the plane of the chip formation region. Following wafer size enlargement, the ratio of the number of chips on the wafer outer region to the total number of chips on the wafer increases, so that delamination from the edge becomes unacceptable. In addition, as the number of interconnect layers increases, delamination from the edge is facilitated. This obstructs development of multi-layer interconnection.

FIGS. 5A to 5D are schematic views showing cross-sectional structures of a wafer edge in the case where interconnect layers are formed by the conventional method. These figures illustrate an example in which a first low-k interlayer film 122, a liner film 123, a second low-k interlayer film 125, and a barrier metal 124 are deposited on a semiconductor substrate 121.

FIG. 5A shows the overall view of the wafer edge. The state of the wafer cross section can be separated into: the top surface of the wafer bevel (a region 1); the side surface of the wafer bevel (a region 2); the back surface of the wafer bevel (a region 3); and the back surface of the wafer edge (a region 4). The region 1 has a stacked structure in which the low-k interlayer film, the liner film, and the barrier metal are smooth, respectively.

FIG. 5B is an enlarged schematic view of the wafer cross section in the region 2. In the region 2, the first low-k interlayer film 122 and the second low-k interlayer film 125 with upward-pointed parts are observed on the semiconductor substrate 121. Also, the region 2 is dotted with the barrier metal layers 124 formed to come onto the wafer side surface during film formation by a sputtering.

FIG. 5C is an enlarged schematic view of the wafer cross section in the region 3. The top of the semiconductor substrate 121 and the first low-k interlayer film 122 are dotted with the barrier metal layers 124 formed to come onto the wafer back surface during film formation by a sputtering. Also, the second low-k interlayer film 125 is deposited unevenly. In particular, some portions of the film 125 located around the barrier metal 124 are extremely thin.

FIG. 5D is an enlarged schematic view of the wafer cross section in the region 4. The top of the semiconductor substrate 121 is dotted with the barrier metals 124 formed to come onto the wafer back surface during film formation by a sputtering.

As is apparent from FIGS. 5A to 5D, when the interconnect layers are formed using the currently-used flow, the wafer edge becomes extremely rough and a number of portions that will serve as points of initiation of delamination are present in the edge.

An object of the present invention is to provide a method for fabricating a semiconductor device which can suppress delamination from a wafer edge by taking measures against the above problems.

A method for fabricating a semiconductor device according to the present invention comprises: the step (a) of forming an insulating film over the top surface of a wafer-shaped semiconductor substrate; the step (b) of forming a protective film over the side and back surfaces of the semiconductor substrate including the insulating film; the step (c) of removing a portion of the protective film located above a chip formation region of the semiconductor substrate to leave at least a portion of the protective film located on an exposed surface of a wafer bevel of the semiconductor substrate; the step (d) of etching, after the step (c), a portion of the insulating film to form an opening in the insulating film; the step (e) of sequentially forming, after the step (d), a barrier film and a metal film in this order over the top surface of the semiconductor substrate; the step (f) of removing the protective film after the step (e); and the step (g) of removing, after the step (f), portions of the metal film and the barrier film provided on the insulating film to form a metal interconnect filling the opening.

With this method, the protective film can be provided to prevent a portion of the insulating film over the side surface of the wafer bevel from being damaged during the etching (particularly dry etching) in the step (d), so that the surface of the insulating film after formation of the interconnect can be kept in a smooth condition. Furthermore, the material of the interconnect such as the barrier metal can also be prevented from coming onto the back surface of the bevel. This suppresses delamination from the wafer edge including the bevel, so that the yields of the semiconductor devices fabricated around the wafer edge can be improved.

The steps (c) and (f) can be conducted by, for example, a spin etching or the like with a chemical solution selectively dissolving the protective film. In these steps, inert gas such as nitrogen may be sprayed on a surface that is not wished to be etched.

In the step (c), by a CMP method, the protective film and the insulating film can be polished and removed in the same step. With this method, the number of process steps can be reduced and concurrently the protective film and the insulating film do not have to be made of materials having etching selectivities with respect to each other.

The insulating film may be made of, for example, an organic-based low-dielectric-constant material such as SiOC.

The steps (a) to (g) shown above can be repeatedly carried out to form multilayer interconnection capable of resisting delamination.

### BRIEF DESCRIPTION OF THE DRAWINGS

FIGS. 1A to 1H are sectional views for explaining a method for fabricating a semiconductor device according to a first embodiment of the present invention, which show an edge of a wafer-shaped semiconductor substrate.

FIGS. 2A to 2G are sectional views for explaining the method for fabricating a semiconductor device according to the first embodiment, which show a chip formation region of the wafer-shaped semiconductor substrate.

FIGS. 3A to 3H are sectional views for explaining a method for fabricating a semiconductor device according to a second embodiment.

FIGS. 4A to 4O are sectional views showing conventional interconnect formation steps.

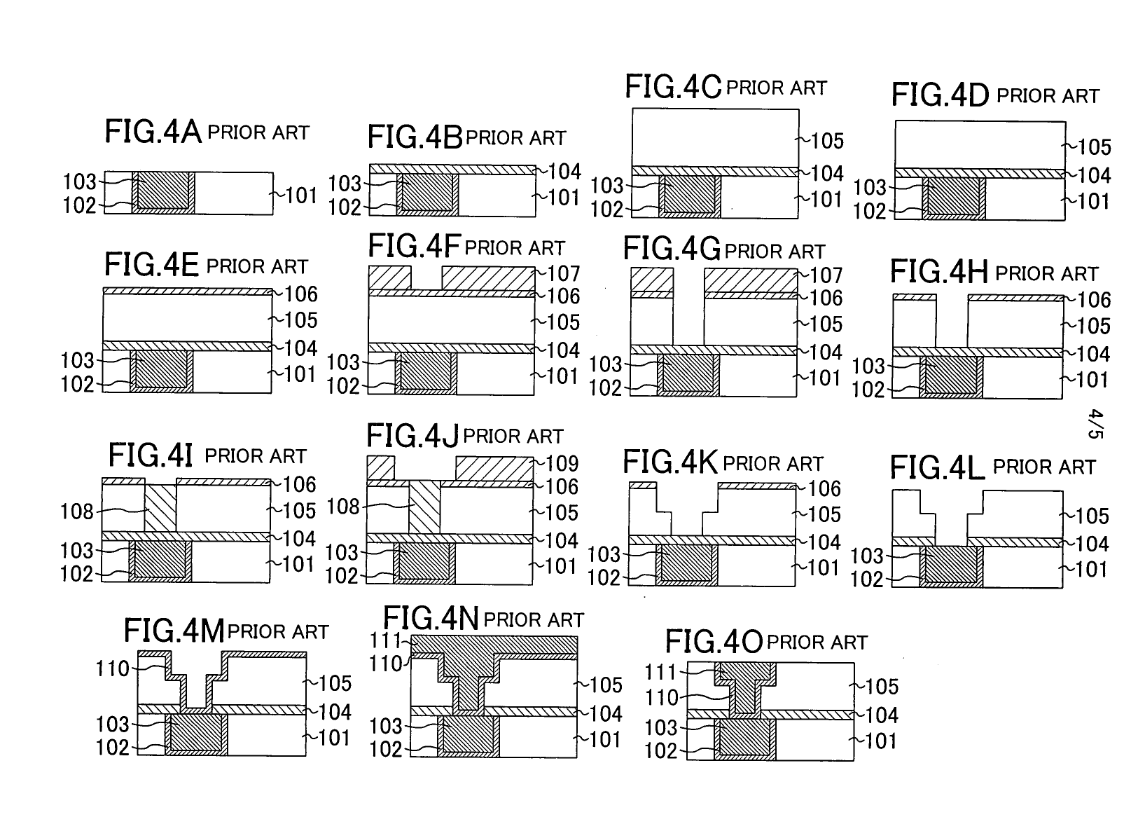

FIGS. 5A to 5D are schematic views showing cross-sectional structures of a wafer edge of a semiconductor substrate in the case where interconnect layers are formed by the conventional interconnect formation steps.

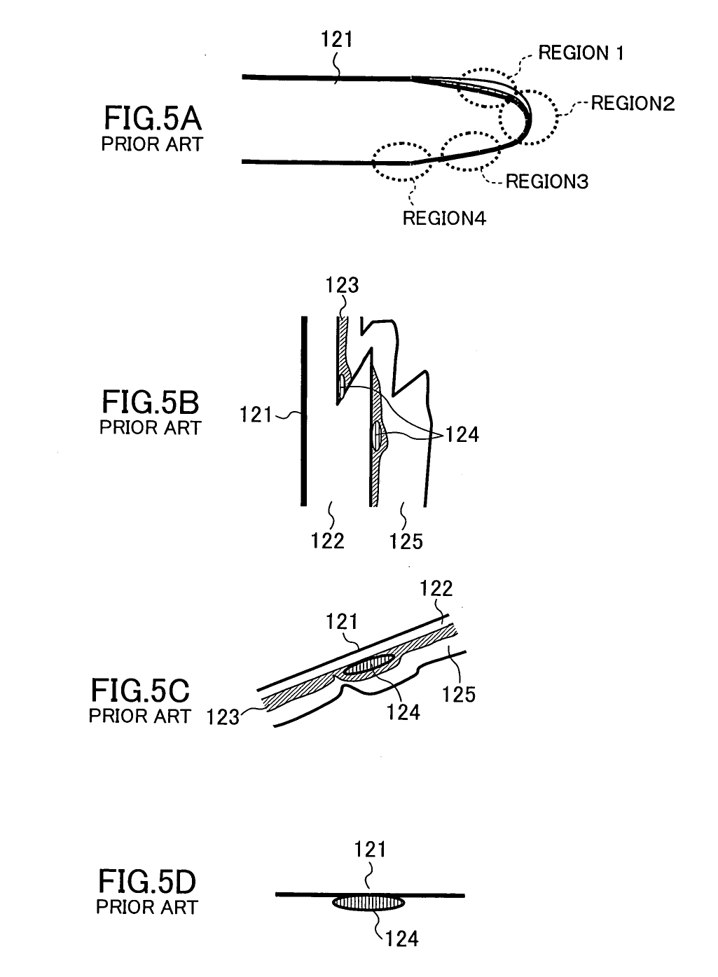

### DETAILED DESCRIPTION OF THE PREFERRED EMBODIMENTS

### First Embodiment

A method for fabricating a semiconductor device according to a first embodiment of the present invention will be described below with reference to the accompanying drawings.

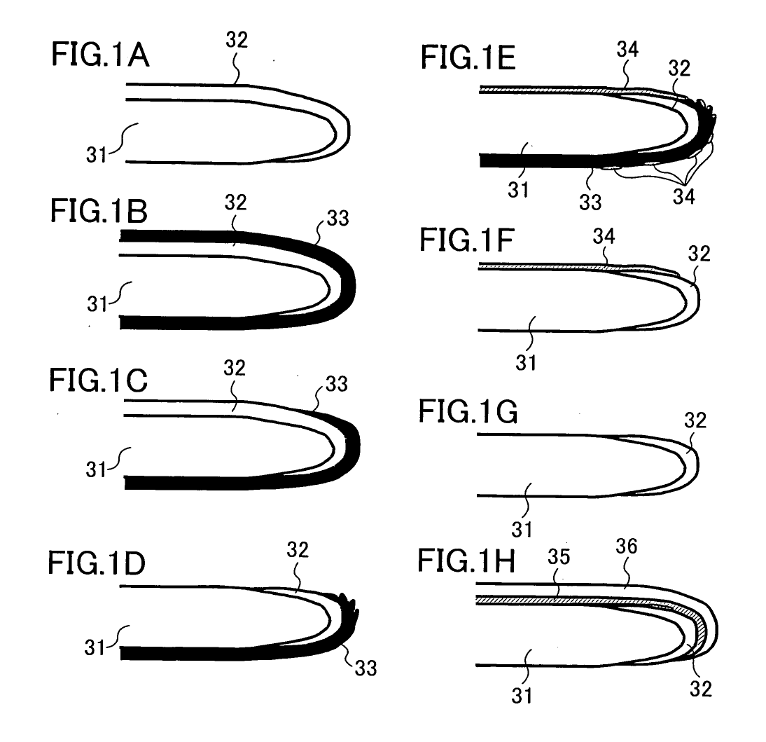

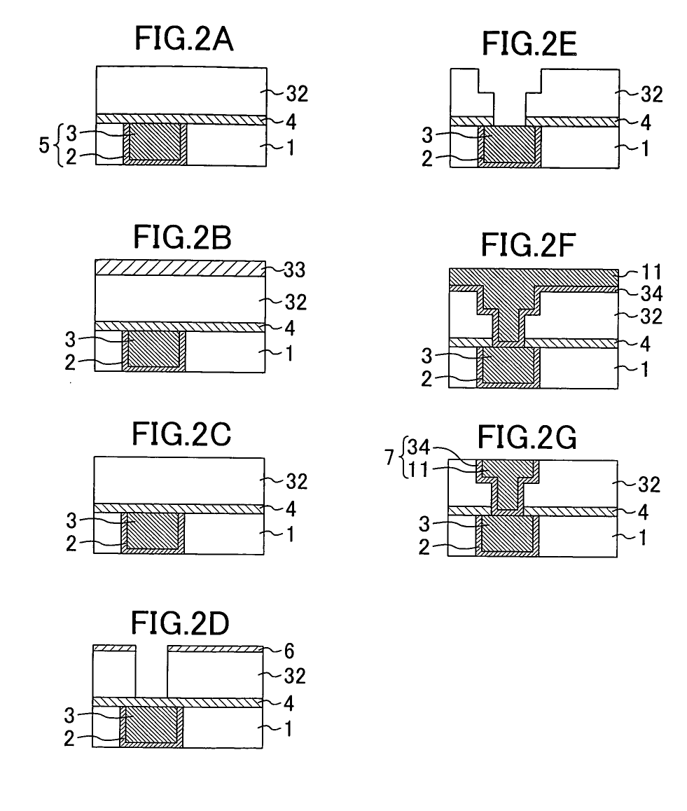

FIGS. 1A to 1H are sectional views of a wafer edge for explaining the method for fabricating a semiconductor device according to the first embodiment. FIGS. 2A to 2G are sectional views of a chip formation region of the wafer for explaining the method for fabricating a semiconductor device according to the first embodiment.

Referring to FIG. 1A, first, an organic-based low-dielectric-constant interlayer film (referred hereinafter to as an organic-based low-k interlayer film) 32 made of SiOC or the like is formed over the top surface of a wafer-shaped semiconductor substrate 31. During this formation, the organic-based low-k interlayer film 32 is formed also on the edge of the semiconductor substrate 31 including the bevel. As shown in FIG. 2A, in a chip formation region on the principal surface of the semiconductor substrate 31, a lower metal interconnect 5, a liner film 4, and the organic-based low-k interlayer film 32 are formed on the semiconductor substrate (not shown). The lower metal interconnect 5 made of a barrier metal 2 and a copper film 3 fills a trench formed in an organic-based low-k interlayer film 1. The liner film 4 made of SiCN or the like is formed on the organic-based low-k interlayer film 1 and the lower metal interconnect 5. The organic-based low-k interlayer film 32 is formed on the liner film 4. The organic-based low-k interlayer film 32 is polished by a CMP method to have a predetermined thickness.

Next, as shown in FIGS. 1B and 2B, using a thermal CVD method, a protective film 33 of, for example, SiO₂ is formed over the surface (the top and bottom surfaces) of the semiconductor substrate 31 including the organic-based low-k interlayer film 32. As the material for the film formed by the thermal CVD, TEOS and O₃ are used. The thermal CVD is carried out at atmospheric pressure and 400° C. (an ozone-TEOS method). In this formation, it is sufficient that the protective film 33 has a thickness enough to protect the organic-based low-k interlayer film 32 in a later etching, for example, a thickness of about 50 nm.

Next, as shown in FIGS. 1C and 2C, a portion of the protective film 33 provided on the top surface of the chip formation region is removed. It is known that the etching rate of the organic-based low-k interlayer film 32 with respect to hydrofluoric acid is very low. By utilizing this characteristic, the top surface (a device surface) of the semiconductor substrate 31 is subjected to a spin etching with a hydrofluoric acid solution to remove the portion of the protective film 33 formed on the top surface of the organic-based low-k interlayer film 32 while thickness reduction of the organic-based low-k interlayer film 32 is prevented. The number of revolutions of the wafer during the spin etching is set at, for example, 2000 rpm. Further, in order to prevent a portion of the protective film 33 formed on the wafer edge from being removed by a hydrofluoric acid solution coming thereonto, a nitrogen gas at a flow rate of 300 L/min is sprayed onto the back surface of the wafer during the spin etching. By employing the procedure described above, the protective film 33 is left on the side and back surfaces of the wafer bevel of the semiconductor substrate 31 and on the back surface of the wafer edge.

As shown in FIG. 2D, on the organic-based low-k interlayer film 32, a cap layer 6 made of a silicon oxide film is formed by a plasma CVD method. Thereafter, a photoresist film (not shown) with a hole-shaped opening is formed on the cap layer 6 provided in the chip formation region. This photoresist film is not formed over the edge of the semiconductor substrate 31. Subsequently, using the photoresist film as a mask, the cap layer 6 and the organic-based low-k interlayer film 32 are dry etched to form a via hole reaching the liner film 4 through the cap layer 6 and the organic-based low-k interlayer film 32. In this etching, as shown in FIG. 1D, portions of the cap layer 6 and the organic-based low-k interlayer film 32 located on the edge of the semiconductor substrate 31 are removed. Then, the photoresist film is removed.

As shown in FIG. 2E, a lithography process and a dry etching process are carried out to form a groove-shaped opening in the organic-based low-k interlayer film 32. Then, using an etch back method, a portion of the liner film 4 located below the via hole in the organic-based low-k interlayer film 32 is removed to form an opened portion above the lower metal interconnect 5. During this etch back, the cap layer 6 is also removed by the etch back. By the process steps shown in FIGS. 2D and 2E, a portion of the protective film 33 provided on the side surface of the wafer bevel of the semiconductor substrate 31 is formed into the shape with upward-pointed parts as shown in FIG. 1D.

As shown in FIGS. 1E and 2F, a barrier metal 34 is deposited over the entire top surface of the semiconductor substrate 31. Then, using a sputtering method and a plating method, a copper film 11 filling the via hole and the opening is deposited on the barrier metal 34. Subsequently, a portion of the copper film 11 adhering to the wafer edge of the semiconductor substrate is removed by a wet etching. After this removal, the side and back surfaces of the wafer bevel and the back surface of the wafer edge are seen to be dotted with the barrier metals 34.

Next, as shown in FIG. 1F, by a spin etching with a hydrofluoric acid solution, portions of the protective film 33 formed on the back surface of the semiconductor substrate 31 and on the side surface of the edge thereof are removed. Since the organic-based low-k interlayer film 32 is difficult to etch with a hydrofluoric acid solution, only the protective film 33 is etched in this step. The portion of the barrier metal 34 deposited to come onto the protective film 33 is also lifted off simultaneously. As a result, the organic-based low-k interlayer film 32 is kept in a smooth condition.

As shown in FIGS. 1G and 2G, using a CMP method, portions of the copper film 11 and the barrier metal 34 provided on the organic-based low-k interlayer film 32 are removed by polishing. Thereby, a second metal interconnect 7 made of the barrier metal 34 and the copper film 11 is formed in the via hole and the opening provided in the organic-based low-k interlayer film 32 in the chip formation region. The lower part of the second metal interconnect 7 serves as a contact plug connected to the lower metal interconnect 5.

As shown in FIG. 1H, a liner film 35 and an organic-based low-k interlayer film 36 are sequentially deposited on the semiconductor substrate 31. Since the surface of the organic-based low-k interlayer film 32 remaining on the edge of the semiconductor substrate 31 is smooth, layers such as the liner film 35 and the organic-based low-k interlayer film 36 also have smoothed surfaces. As a result of this, delamination does not arise.

As described above, with the method of the first embodiment, a rough film that will serve as a point of initiation of delamination is prevented from being formed on the wafer bevel of the semiconductor substrate. Moreover, no barrier metal stays onto the back surface of the wafer edge including the wafer bevel. Thus, with the method of the first embodiment, delamination from the wafer edge can be reduced even though multi-layer interconnection is made. Therefore, the method of the first embodiment can be used to improve the yields of the semiconductor devices fabricated around the edge of the chip formation region.

Furthermore, since, as an interlayer film, an organic-based low-k interlayer film is used which has a low etching rate with respect to hydrofluoric acid, a silicon oxide film capable of being deposited at low cost can be employed as a protective film. However, the protective film may be formed of any material that has the selectivity with respect to the interlayer insulating film. Moreover, the interlayer insulating film may be formed of an insulator other than an organic-based low-dielectric-constant substance, or formed of silicon oxide.

In the first embodiment, description has been made of the formation method of interconnect layers in the case of using a Cu dual-damacene method. Also in the case of a Cu single-damacene method, the same procedure can be used to suppress delamination from the edge. As a formation method of the protective film, an atmospheric pressure CVD method (an ozone-TEOS method) is exemplarily employed. However, it is sufficient to employ the method in which a protective film is deposited on the entire surface of a wafer edge, and another approach such as a low pressure CVD method or the like using silane gas and oxygen gas can be employed.

### Second Embodiment

A method for fabricating a semiconductor device according to a second embodiment of the present invention will be described below with reference to the accompanying drawings. The method of the second embodiment simplifies fabrication steps as compared to that of the first embodiment by modifying the step of depositing a protective film and the step of removing a portion of the protective film on a device surface.

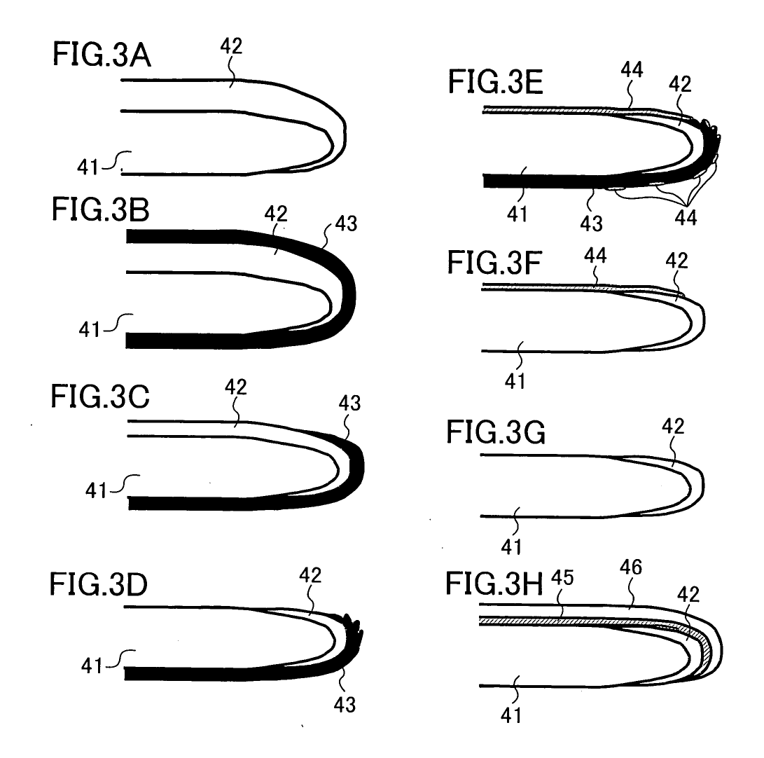

FIGS. 3A to 3H are sectional views for explaining the method for fabricating a semiconductor device according to the second embodiment. These figures illustrate an edge of a wafer-shaped semiconductor substrate.

As shown in FIG. 3A, first, in the edge of a wafer-shaped semiconductor substrate 41, an organic-based low-k interlayer film 42 is formed on the semiconductor substrate 41. Unlike the first embodiment, the organic-based low-k interlayer film 42 is not polished in this step.

Next, as shown in FIG. 3B, using a thermal CVD method, a protective film 43 of SiO₂ is formed over the entire surface (which includes the top and bottom surfaces) of the semiconductor substrate 41 including the wafer edge. As the material for the film formed by the thermal CVD, use is made of TEOS and O₃. The thermal CVD is carried out at atmospheric pressure and 400° C. (an ozone-TEOS method). In this formation, it is sufficient that the thickness of the protective film 43 is set at, for example, 50 nm.

As shown in FIG. 3C, using a CMP method, a portion of the protective film 43 formed over the top surface of the semiconductor substrate 41 is polished, and without a break, the organic-based low-k interlayer film 42 is polished to have a predetermined thickness. Since the organic-based low-k interlayer film 42 has the structure in which carbon is introduced into silicon oxide, it can be polished continuously after the polishing of the protective film 43 made of a silicon oxide film and on the same polishing condition. By a series of polishings, the organic-based low-k interlayer film 42 is left on the top and side surfaces of the wafer bevel of the semiconductor substrate 41, while the protective film 43 is left over the side surface of the wafer bevel of the semiconductor substrate 41 and the back surface of the semiconductor substrate 41.

As shown in FIG. 3D, using a photoresist film (not shown) formed with a pattern by a lithography process, the organic-based low-k interlayer film 42 is dry etched, and then the photoresist film is removed. Thereby, a via hole reaching the liner film is formed (see FIG. 2D). Subsequently, a lithography process and a dry etching process are carried out to form a groove-shaped opening in the organic-based low-k interlayer film 42 (see FIG. 2E). In this step, by these dry etchings, a portion of the protective film 43 provided on the side surface of the wafer bevel of the semiconductor substrate 41 is formed into the shape with upward-pointed parts.

As shown in FIG. 3E, a barrier metal 44 is deposited over the entire top surface of the semiconductor substrate 41. Then, using a sputtering method and a plating method, a copper film (not shown) filling the via hole and the opening is deposited on the barrier metal 44 (see FIG. 2F). Subsequently, a portion of the copper film adhering to the wafer edge of the semiconductor substrate 41 is removed by a wet etching. After this removal, the side and back surfaces of the wafer bevel and the back surface of the wafer edge are seen to be dotted with the barrier metal 44.

Next, as shown in FIG. 3F, by a spin etching with a hydrofluoric acid solution, portions of the protective film 43 formed on the back surface of the semiconductor substrate 41 and on the side surface of the edge thereof are removed. Since the organic-based low-k interlayer film 42 is difficult to etch with a hydrofluoric acid solution, only the protective film 43 is etched in this step. The portion of the barrier metal 44 deposited to come onto the protective film 43 is also lifted off simultaneously. As a result, the organic-based low-k interlayer film 42 is kept in a smooth condition.

As shown in FIG. 3G, the barrier metal 44 and the copper film are removed by polishing using a CMP method, whereby a second metal interconnect is formed in the chip formation region of the semiconductor substrate 41 (see FIG. 2G).

As shown in FIG. 3H, a liner film 45 and an organic-based low-k interlayer film 46 are sequentially deposited on the semiconductor substrate 41. Since the surface of the organic-based low-k interlayer film 42 remaining on the edge of the semiconductor substrate 41 is smooth, layers such as the liner film 45 and the organic-based low-k interlayer film 46 also have smoothed surfaces. This prevents delamination.

As described above, with the method of the second embodiment, a rough film that will serve as a point of initiation of delamination is prevented from being formed on the wafer bevel of the semiconductor substrate 41. Moreover, no barrier metal stays onto the back surface of the wafer edge of the semiconductor substrate 41 including the wafer bevel. Thus, with the method of the second embodiment, delamination from the wafer edge can be reduced even though multi-layer interconnection is made. Therefore, the method of the second embodiment can be used to improve the yields of the semiconductor devices fabricated around the edge of the chip formation region.

Furthermore, since, as an interlayer film, an organic-based low-k interlayer film is used which has a low etching rate with respect to hydrofluoric acid, a silicon oxide film capable of being deposited at low cost can be employed as a protective film.

With the method for fabricating a semiconductor device according to the second embodiment, since the protective film 43 and the organic-based low-k interlayer film 42 are continuously polished by a CMP method in the step shown in FIG. 3C, the interconnect formation steps can be more simplified than those of the method of the first embodiment.

Note that the protective film may be formed of any material. The interlayer insulating film may be formed of an insulator other than an organic-based low-dielectric-constant substance, or formed of silicon oxide. In the method of the second embodiment, polishing is done in the step shown in FIG. 3C. Therefore, even though the interlayer insulating film and the protective film are both made of silicon oxide, delamination can be prevented.

In the present invention, description has been made of the formation method of interconnect layers in the case of using a Cu dual-damacene method. Also in the case of a Cu single-damacene method, the same procedure can be used. As a formation method of the protective film, an atmospheric pressure CVD method (an ozone-TEOS method) is exemplarily employed. However, it is sufficient to employ the method in which a protective film can be deposited on the entire surface of a wafer edge, and another approach such as a low pressure CVD method or the like using silane gas and oxygen gas can also be employed.

As described above, the method of the present invention is useful for forming an interconnect layer capable of resisting delamination, and usable for fabricating a semiconductor chip having various types of circuits formed thereon.

What is claimed is:

1. A method for fabricating a semiconductor device, comprising:
the step (a) of forming an insulating film over the top surface of a wafer-shaped semiconductor substrate;
the step (b) of forming a protective film over the side and back surfaces of the semiconductor substrate including the insulating film;
the step (c) of removing a portion of the protective film located above a chip formation region of the semiconductor substrate to leave at least a portion of the protective film located on an exposed surface of a wafer bevel of the semiconductor substrate;
the step (d) of etching, after the step (c), a portion of the insulating film to form an opening in the insulating film;
the step (e) of sequentially forming, after the step (d), a barrier film and a metal film in this order over the top surface of the semiconductor substrate;
the step (f) of removing the protective film after the step (e); and
the step (g) of removing, after the step (f), portions of the metal film and the barrier film provided on the insulating film to form a metal interconnect filling the opening.

2. The method of claim 1,
wherein the insulating film and the protective film are made of materials having etching selectivities with respect to each other, and
in the step (c), the protective film is selectively removed by a spin etching with an etching solution.

3. The method of claim 1, further comprising, after the step (a) and before the step (b), the step of polishing the insulating film by a CMP method to have a predetermined thickness.

4. The method of claim 1,
wherein in the step (c), by a CMP method, a portion of the protective film located over the top surface of the semiconductor substrate is removed and then the insulating film is polished to have a predetermined thickness.

5. The method of claim 1,
wherein the insulating film is made of an organic-based insulating material, and
the protective film is made of silicon oxide.

6. The method of claim 1,
wherein in the step (f), the protective film is removed by a spin etching with an etching solution.

7. The method of claim 1,
wherein in the step (e), the protective film is removed by a spin etching with an etching solution.
